(19) United States
(12) Patent Application Publication
(10) Pub. No.: US 2006/0008749 A1
(43) Pub. Date: Jan. 12, 2006

(54) Method for manufacturing of a mask blank for EUV photolithography and mask blank

(76) Inventors: Frank Sobel, Meiningen (DE); Lutz Aschke, Wetter (DE); Guenter Hess, Meiningen (DE); Hans Becker, Meiningen (DE); Markus Renno, Meiningen (DE); Frank Schmidt, Jena (DE); Oliver Goetzberger, Meiningen (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/885,898

(22) Filed: Jul. 8, 2004

(51) Int. Cl. B32B 17/06; B32B 9/00; G03C 5/00; B32B 15/00; G03F 1/00

(52) U.S. Cl. 430/394; 430/5; 428/428; 428/432

(57) ABSTRACT

The invention relates to a method for manufacturing of a mask blank for extreme ultraviolet (EUV) photolithography, comprising the steps of: providing a substrate having a front surface and a back surface; depositing a film comprising tantalum nitride (TaN) on said front surface of said substrate for absorbing EUV light used during a photolithographic process; and depositing a conductive coating on said back surface of said substrate. Preferably, ion beam sputtering is used for depositing the film comprising tantalum nitride (TaN) and/or the conductive coating on the back surface of the substrate. Preferably, Xenon is used as a sputter gas for ion beam sputtering. Another aspect of the present invention relates to a mask blank for extreme ultraviolet (EUV) photolithography.

### TECHNICAL FIELD OF THE INVENTION

The present invention relates in general to a mask blank and a method for manufacturing of a mask blank for EUV photolithography. In particular the present invention relates to a mask blank which can be manufactured at low costs while offering the possibilities of easy handling and high-quality exposure.

### BACKGROUND OF THE INVENTION

Mask blanks of the above kind are widely used as substrates for manufacturing of photo masks used for photolithography. Due to the ever-increasing demand for smaller structures and higher structure densities in production of semiconductors, integrated circuits and micro-electromechanical devices (MEMs), the acceptable defect density and defect size on wafers decreases. Therefore, also the quality demands for photo masks and hence also for mask blanks for manufacturing of such photo masks are increasing, in particular with regard to the density and the maximum size of defects.

As is well-known to a person skilled in the art, photo masks in the sense of this application may be subdivided into three groups, namely binary photo masks, phase shifting photo masks and extreme ultraviolet (EUV) photo masks.

In many photolithographic applications an absorbing layer suited for absorbing a wavelength used for a photolithographic process is deposited on a photo mask. For example, a binary photo mask may comprise a layer or film of an opaque or non-transmitting material. This layer may be covered by an anti-reflection coating effective at a wavelength used for a photolithographic process. The layer is patterned in such a way as to produce a binary mask suitable for exposing integrated circuits on a photoresist layer deposited on a wafer or semiconductor substrate.

As the wavelengths used for photolithography are decreasing, there exists a need for providing absorber layers, in particular anti-reflective absorber layers that are suitable at short wavelengths, in particular in the EUV spectral range (between 13 and 14 nm). Such absorber layers have to be provided with a quality sufficient for the demands of present and future photolithographic processes.

Photo mask blanks for use in EUV photolithography comprise various layers that have to be deposited with high quality for achieving high yields. At the same time, EUV photolithography requires easy handling of photo masks without low or zero abrasion and the like caused by mechanical handling of the photo masks for processing. As is well known to the person skilled in the art, effects like abrasion and the like cause degradation of the photo masks and defects on the substrates to be exposed. Accordingly, there exists the need to provide photo masks blanks for use in EUV photolithography that can be manufactured easily while ensuring reliable handling and high yields during exposure of substrates with EUV radiation.

### RELATED ART

EP 346 828 B1 discloses an X-ray absorber for use in X-ray lithography and a method for fabrication thereof by sputtering. The X-ray absorbing film comprises tantalum (Ta) as a base material together with one or more of the elements aluminum (Al), titanium (Ti), silicon (Si) and molybdenum (Mo) as additive element(s) in a total amount of from 0.5 to 10% by weight of the material of the X-ray absorbing film. According to EP 346 828 B1, an X-ray absorbing film of tantalum (Ta) as the base material has a significantly reduced stress in the sputtered film if a limited amount of one or more of the above additive element(s) is (are) added to the base material. Other heavy metals, such as tungsten or gold, did not show this stress-reducing effect. Use of nitrogen as an additive element is not disclosed by EP 346 828 B1. Furthermore, the techniques disclosed by EP 346 828 B1 are not suited for manufacturing of photo masks for EUV lithography.

Patent Abstracts of Japan publication number 63076325 A, published on Apr. 6, 1988, discloses use of tantalum nitride (TaN) as an X-ray absorber film as a mask for X-ray lithography. The film of tantalum nitride is sputtered on a substrate at low temperatures. Therefore, the film is deposited in an amorphous state. The target used for sputtering may consist of pure tantalum or of tantalum nitride. The absorber layer is not deposited by means of ion beam sputtering.

WO 98/54377 discloses a method for stress-tuning tantalum and tantalum nitride films to be either in tension or in compression or to have a particularly low stress for use in semiconductor interconnect structures. Stress-tuning is achieved by using ion metal plasma (IMP) sputter deposition for depositing the tantalum or tantalum nitride film.

WO 02/18653 A2 discloses a method for depositing a nitrogen rich tantalum nitride (TaN) film to be used with low-k dielectric films. Such films are useful in preventing interference and cross talk between adjacent metal films, lines and other conducting features in semiconductors, in particular when the overall thickness of the dielectric material disposed between conducting features is to be reduced. A target is exposed to a nitrogen rich atmosphere prior to sputtering the target and exposition of the sputtered target material onto a substrate. Thereafter, the flow of N₂ is controlled during processing to create a desired nitrogen concentration in the film. WO 02/18653 A2 does not relate to the manufacturing of photo mask blanks.

U.S. Pat. No. 6,110,598 relates to use of tantalum nitride films as interconnections and electrodes in liquid crystal displays (LCDs).

Patent Abstracts of Japan 2000353658 A discloses an X-ray mask and a method for manufacturing the same. The X-ray mask comprises an absorber pattern comprising a tantalum alloy deposited on a base material layer formed of tantalum nitride. The tantalum layers are formed by a sputtering method using a plasma excited at its electron cyclotron resonance frequency.

US 2004/0041102 A1 discloses a method and configuration for compensating for unevenness in the surface of a EUV reflection mask. Unevenness in the surface is measured and parameters of the compensation method are calculated. For compensating the unevenness, an ion beam is directed to a back surface of the mask. The radiation dose of the ion beam is adjusted in accordance with the parameters calculated. By ion beam irradiation, the lattice structure of the substrate is locally influenced by the doping at the position on the back surface. Also disclosed is the use of low thermal expansion materials for the mask substrate and the deposition of a conductive layer onto the back surface of the substrate enabling the use of electrostatic chucks for holding or chucking the mask from the backside.

### SUMMARY OF THE INVENTION

It is a further object of the present invention to provide a method for manufacturing of a mask blank for extreme ultraviolet (EUV) lithography suitable for the production of a photo mask comprising small or fine structures.

It is a further object of the present invention to provide a method for manufacturing of a mask blank for EUV photolithography having a particularly low stress induced in an absorber film deposited on a surface of the mask blank.

Still a further object of the present invention is to provide a method for manufacturing of a mask blank for EUV photolithography having a particularly low defect density and/or a particularly good homogeneity.

Still a further object of the present invention is to provide a method for manufacturing of a mask blank for EUV photolithography for ensuring good absorption of UV or EUV radiation used for photolithography, good dry etching properties such as feature size, pattern transfer, etch selectivity, etch bias or CD uniformity, good reflectivity at an optical inspection wavelength, in particular in near ultraviolet spectral range of optical inspection wavelengths.

Still a further object of the present invention is to provide a mask blank for EUV photolithography that can be handled smoothly and securely while ensuring high yield when used in photolithographic processes.

Still a further object of the present invention is to provide a mask blank suitable for use in EUV photolithography for the production of a photo mask comprising small or fine structures.

Still a further object of the present invention is to provide a mask blank for EUV photolithography having a particularly low stress induced in an absorber film deposited on a surface thereof.

According to a first aspect of the invention there is provided a method for manufacturing of a mask blank for extreme ultraviolet (EUV) photolithography, comprising the steps of: providing a substrate having a front surface and a back surface; depositing a film comprising tantalum nitride (TaN) on said front surface of said substrate for absorbing EUV light used for a photolithographic process; and depositing a conductive coating on said back surface of said substrate.

According to the present invention the TaN layer ensures a high absorption of EUV light for enabling high contrast ratios and high yields in EUV photolithography. At the same time the conductive coating on the back surface ensures that the mask blank may be held at the back surface and over large areas by means of an electrostatic holding device (electrostatic chuck). Because the electrostatic holding device can be in contact with a large area of the rear side of the substrate, only low holding forces are necessary. These result in turn in less abrasion and hence in a lower risk of contamination during handling the photo mask or during photolithographic process steps. In addition, a mask blank according to the invention may be held and handled very gently. An electric potential applied to the electrostatic holding device and/or to the back surface of the mask blank can be advantageously controlled and gently switched on and off. This enables sudden applications of force to the mask blank to be avoided to a large extent, which results in even less abrasion and even lower particle formation according the present invention. The large area of contact between the mask blank and the electrostatic holding device may also be used to pull the mask blank straight, for example, if it is bent or under tension, in order thus to reduce stress.

According to another aspect of the present invention the step of depositing said film comprising tantalum nitride (TaN) on said front surface of said substrate comprises depositing said film by ion beam sputtering, wherein said step of ion beam sputtering comprises directing a particle beam of ions onto a target within a vacuum chamber, said target consisting at least of tantalum. According to the present invention ion beam sputtering (IBS) or ion beam deposition (IBD) enables the manufacturing of high quality mask blanks and photo masks in a surprisingly reliable and cost-effective manner. Films produced by ion beam sputtering or ion beam deposition (IBD) are highly stable due to a high deposition energy that is enabled by the momentum transfer occurring in the sputtering process. According to the present invention, the deposition energy is preferably >1 eV, more preferably >10 eV, more preferably >100 eV and even more preferably >500 eV. Furthermore, ion beam deposition provides a high reproducibility.

Due to the ever increasing demand for providing smaller and smaller structures on a photo mask, the exposure wavelengths used for photolithography tend to shorter wavelengths and, therewith, the quality demands for photo mask blanks still increase considerably.

In this respect, a low defect density is an important parameter of a photo mask blank. Defects can be caused by the manufacturing process of the photo mask blank, in particular by particles, liquids or gases. Such defects may disadvantageously cause a loss of adhesion of the layers, either locally or over the whole photo mask blank. As a photo mask blank will be exposed, developed, etched, cleaned from photo-resist and exhibited to numerous cleaning steps, a location with low adhesion may cause a defect of the photo mask. Due to the advantageously high adhesion of the sputtered films the defect level can be decreased substantially according to the present invention. Defects may also be caused by abrasion and other mechanical effects during handling and/or holding photo masks. Due to the conductive coating on the back surface of the substrate, a photo mask according to the present invention can be held and/or handled very gently without the risk of causing defects due to abrasion and other mechanical effects.

According to the present invention, for ion beam sputtering a particle beam of ions can be directed onto a target within a vacuum chamber, said target consisting at least of tantalum (Ta) and consisting more preferably of high purity tantalum. Thereby material or particles, e.g. atoms or small clusters being sputtered from the target, emerge from the target towards the substrate, so that a layer or film is grown on the substrate or on another layer or film already grown on the substrate. Due to their availability, according to the present invention rare gas ions, e.g. Xenon (Xe) or Argon (Ar), are directed onto the target for sputtering material or particles therefrom. Experiments of the inventors revealed that sputtered tantalum nitride layers with low stress induced can be obtained according to the present invention, if rare gas ions are used for ion beam sputtering.

According to an important preferred aspect of the present invention, a particle beam of Xenon (Xe) ions is directed onto the target for sputtering material or particles therefrom. With Xenon ions the momentum transfer is even higher and more efficient. Experiments of the inventors surprisingly revealed that sputtered tantalum nitride layers with even lower stress induced can be obtained according to the present invention, if Xenon (Xe) ions are used for ion beam sputtering. Furthermore, such layers were very homogenous and exhibited low defect levels.

The ion beam sputtering can be performed in the presence of a nitrogen gas within said vacuum chamber while directing said particle beam of rare gas ions onto said target. The presence of nitrogen atoms within the vacuum chamber enables using a target consisting of high purity tantalum while the composition of the tantalum nitride (TaN) layer can be adjusted by properly adjusting the flow or concentration of nitrogen within the vacuum chamber.

Ion beam sputtering can be performed in the presence of an oxygen gas within the vacuum chamber as well while directing the particle beam of rare gas ions onto the target. This enables varying the concentration of doping gases within certain ranges within the anti-reflective layer so as to fit optical reflectivity needs. Furthermore, this enables not to sputter the film with the same deposition parameters as for the TaN film.

The ion beam sputtering can be performed such that a stress induced in said film, as measured by a peak-to-valley bending of said substrate after depositing said film, is better than 2.6 micron for a 6×6 Inch square substrate. Such a low stress can be obtained easily when directing a particle beam of Argon ions onto the tantalum target.

More preferably the ion beam sputtering can be performed such that a stress induced in said film, as measured by a peak-to-valley bending of said substrate after depositing said film, is better than 1.56 micron for a 6×6 Inch square substrate. Such a low stress can be obtained easily when directing a particle beam of Xenon ions onto the tantalum target.

The ion beam sputtering can be performed such that a defect level of defects within said film of a size larger than 0.2 micron PSL (polystyrene latex spheres) is smaller than 0.035 defects per square centimeter at a limit below 200 nm, more preferably 0.001 defects per square centimeter at a limit below 150 nm and most preferably 0.001 defects per square centimeter at a limit below 50 nm.

According to another aspect of the present invention ion beam sputtering of said tantalum nitride layer can be performed such that the absorption of said film at an extreme ultraviolet wavelength, preferably at a wavelength of 13.5 nm, is better than 97%, preferably better than 99% and most preferably better than 99.5%.

According to another aspect of the present invention, an anti-reflection coating can be deposited on the tantalum nitride film, said anti-reflection coating being anti-reflective at an optical inspection wavelength in a near ultraviolet spectral range. While it is difficult and costly to produce and manipulate light beams at wavelengths in the EUV spectral range, light beams at wavelengths in the near UV spectral range can be generated and manipulated easily and in a cost efficient manner. Therefore, optical inspection of a photo mask blank according to the present invention can be performed easily at optical wavelengths that are more suitable for inspection. Preferably, the anti-reflection coating is effective at an optical inspection wavelength in the range between 150 nm and 400 nm, most preferably at an optical inspection wavelength of 365 nm.

The anti-reflection coating can be TaON. Such a coating can be sputtered easily onto the tantalum nitride film if the ion beam sputtering is performed in the presence of an oxygen gas and of a nitrogen gas within the vacuum chamber while directing the particle beam of ions onto said target. Ion beam sputtering of the TaON film is preferably performed under identical conditions as used for ion beam sputtering of the TaN film, but in the presence of an additional oxygen gas within the vacuum chamber. Thus, the composition of the TaON film can be adjusted easily by adjusting the concentrations or flows of the oxygen and nitrogen gas within the vacuum chamber.

By varying the ratio of the thickness of the anti-reflection layer to the thickness of the tantalum nitride film the reflectivity of the anti-reflection layer at the optical inspection wavelength, in particular at the optical inspection wavelength in the near UV spectral range, can be adjusted. For this purpose the above ratio can lie within the range between 0.4 and 0.12.

The anti-reflection coating on the tantalum nitride film can be conducted such that a variation of reflectivity at an optical inspection wavelength of 365 nm is smaller than 6% (3σ), preferably smaller than 5% (3σ) and most preferably smaller than 4% (3σ).

According to the present invention, the substrate can consist of a material having an extremely low coefficient of thermal expansion. As is well-known to a person skilled in the art the zero crossing of the temperature dependency of the coefficient of thermal expansion (CTE) can be adjusted easily by varying the material composition and/or treatment parameters of the substrate so as to correspond to a temperature expected during use in a photolithographic apparatus used for photolithographic exposure. Such an expected operating temperature may lie within a temperature range between 20° C. and 40° C. Most preferably, the CTE is smaller than approximately 5 ppb/K within a temperature range between 19° C. and 25° C.

According to another aspect of the present there is provided a mask blank for photolithography, in particular for use in EUV photolithography. Such a mask blank is provided by using any of the above methods and techniques.

### DESCRIPTION OF THE DRAWINGS

The above and further advantages, features and problems to be solved will become more apparent to a person skilled in the art when studying the present application together with the accompanying drawings, wherein:

FIG. 1 shows a schematic cross section of a EUV photo mask blank according to the present invention;

FIG. 2 shows an enlarged cross section of the absorber layer according to FIG. 1;

FIG. 3 shows results of a reflection measurement at an optical inspection wavelength in the near ultraviolet spectral range in a two-dimensional plot of the photo mask blank according to FIG. 1;

FIG. 4a shows a three-dimensional plot of stress induced in a tantalum nitride (TaN) film according to FIG. 1, as measured by a peak-to-valley bending of said substrate after depositing said film, in the case of ion beam sputtering (IBS) using Argon (Ar) ions; and

FIG. 4b shows a three-dimensional plot of stress induced in a tantalum nitride (TaN) film according to FIG. 1, as measured by a peak-to-valley bending of said substrate after depositing said film, in the case of ion beam sputtering (IBS) using Xenon (Xe) ions.

### DETAILED DESCRIPTION OF PREFERRED EMBODIMENTS

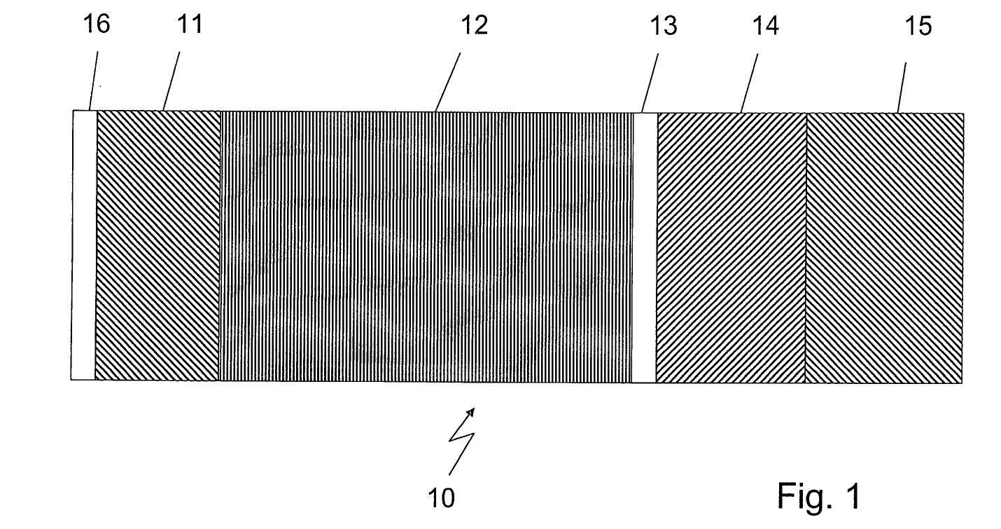

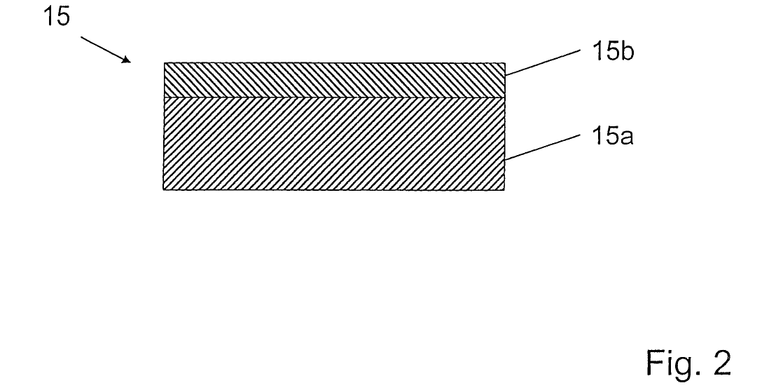

The photo mask blank 10 according to the present invention, as shown in and explained with reference to FIG. 1 below, is produced by ion beam sputtering (IBS) or ion beam deposition (IBD) . For the purpose of disclosing a method and an apparatus for manufacturing the photo mask blank according to the present application, reference is made to the applicant's co-pending U.S. patent application Ser. No. 10/367,539 filed on Feb. 13, 2003, the whole content of which is hereby explicitly incorporated by reference.

An ion beam deposition apparatus for use according to the present application comprises a vacuum chamber, wherein an ion deposition source creates a first ion beam. A sputter gas is guided into the deposition ion source and is ionized inside by atomic collisions with electrons that are accelerated by an inductively coupled electromagnetic field. The first ion beam is then imaged or directed onto the target consisting of high purity tantalum (Ta) . Thereby, cascades of atomic collisions are caused so that target atoms are blasted out of the surface of the target. This process of sputtering or vaporizing the target is called the sputter process.

Various parameters can be adjusted to influence the momentum transfer function between the primary ions and the target atoms to optimize the layer quality. Some preferred parameters are as follows:
mass of the primary ions;
ion current of primary ions;
energy of the first ion beam as defined by the acceleration voltage;
angle of incidence of the first ion beam with respect to a normal onto a target surface;
density and purity of the target.

The momentum transfer to the target atoms is most efficient, when the mass of the primary ions is equivalent to the mass of the target atoms. According to the present invention, preferably rare gas ions such as Argon (Ar) or Xenon (Xe), are used as the sputter gas. Most preferably Xenon ions are used as the sputter gas.

Several parameters, such as the relative orientation of the target, substrate and ion beam, can be used to adjust or control the energy and/or the angle of incidence of the first ion beam and of the sputtered ions. As the sputtered ions hit the substrate with an energy, which is much higher than with conventional vapor deposition, deposition of highly stable and dense layers or films on substrates is enabled according to the present invention.

Furthermore, an apparatus for ion beam sputtering a photo mask blank according to the present invention comprises an assist particle source for creating a second particle or ion beam that is directed towards the substrate, e.g. for flattening, conditioning, doping and/or further treatment of the substrate and/or films deposited on the substrate. In particular, the second ion beam is used to
dope tantalum films with oxygen or nitrogen;
clean the substrate, e.g. with an oxygen plasma before deposition;
improve the interface quality of films by flattening the films.

### EUV PHOTO MASK BLANK (EXAMPLE 1)

FIG. 1 a schematic cross section of an exemplary layer or film system of an EUV photo mask blank 10 according to the present invention.

The photo mask blank 10 comprises a substrate 11 of a material having an extremely low coefficient of thermal expansion (CTE). Preferably, the CTE is smaller than approx. 5 ppb/K in the temperature range between 19° C. and 25° C., but can, of course, be adjusted easily to other conditions present during photolithographic exposure. Referring to FIG. 1 the substrate 11 has a front surface and a back surface.

On the front surface of the substrate 11 there is provided a high-reflective multi-layer stack 12 comprising e.g. 40 bi-layers or alternating films of Molybdenum (Mo) and silicon (Si) . Each layer pair or film pair has a thickness of 6.8 nm and the fraction of Molybdenum is 40%, resulting in a total thickness of 272 nm of the Mo/Si multi-layer stack 12. The multi-layer stack 12 represents an EUV mirror and is protected by a 11 nm silicon capping layer or film 13, which is deposited on top of the multi-layer stack 12 and protects the multi-layer stack 12 from contamination.

On top of the Silicon capping layer 13 a SiO₂ buffer layer 14 having a thickness of 60 nm is deposited. Furthermore, on top of the buffer layer 14 an absorber layer 15 of tantalum nitride is deposited for absorbing EUV light used for photolithographic exposure. Inter alia, the buffer layer 14 can prevent over etch on the capping layer 13 during repairing the absorber layer 15 (TaN/TaON). For providing a structured or patterned photo mask, the absorber layer 15 of the photo mask blank 10 is patterned as will be apparent to a person skilled in the art.

Referring to FIG. 1 a conductive coating 16 is provided on the back surface of the substrate 11. As the back surface of the substrate is provided with an electrically conductive coating, the mask blank may be held and handled using an electrostatic holding device. The electrically conductive coating on the rear side of the mask blank enables electrostatic charges from the mask blank to be avoided or dissipated in an even more effective way, for example during transportation or handling.

In principle, all metallization techniques providing an adequate metallization quality suitable for the coating of the back surface of the substrate are possible. Ion-beam-assisted deposition, in particular ion-beam-assisted sputtering, has been found to be particularly suitable. With this coating technology, an ion beam is directed onto a target whose material peels off into a vacuum. The target is located in the vicinity of the substrate to be coated and the substrate is coated by the detached target substance by sputtering. Even though this coating method is relatively complex and expensive, it has been found to be particularly suitable for coating masks or mask blanks because the layers applied are particularly homogeneous and defect-free. Ion-beam-assisted deposition may be used to apply a metal or a mixture of two or more metals or dielectrics. As regards the details of the ion-beam-assisted deposition of metals and dielectrics, reference is made to the applicant's co-pending U.S. patent application Ser. No. 10/367,539 with the title ‘Photo Mask Blank, Photo Mask, Method and Apparatus for Mask Blank, Photo Mask, Method and Apparatus for Manufacturing of a Photo Mask Blank’ with a filing date of 13 Feb. 2003, the contents of which are expressly incorporated in this application by reference.

The electrically conductive coatings applied in this way onto the back surface of the substrate are characterised by several advantageous properties, particularly with regard to abrasion and resistance, as described in detail in the applicants co-pending U.S. patent application Ser. No. 10/825,618 filed on Apr. 16, 2004 ‘Mask blank for use in EUV lithography and method for its production’ and in the applicant's German patent application no. 103 17 792.2-51 filed on Apr. 16, 2003, the whole contents of which are hereby explicitly incorporated by reference for the purpose of disclosing the present invention. In particular, the electrically conductive coatings on the back surface of the substrate can be characterized by the following characteristics:
the resistance of the electrically conductive coating to abrasion with a cloth according to DIN 58196-5 (German Industry Standard) falls into at least category two;
the resistance of the electrically conductive coating to abrasion with an eraser according to DIN 58196-4 (German Industry Standard) falls into at least category two;
the adhesive strength of the electrically conductive coating determined in an adhesive tape test according to DIN 58196-6 (German Industry Standard) corresponds to a detachment of substantially 0%;
with a layer thickness of approximately 100 nm, the resistivity of the electrically conductive coating is at least approximately 10⁻⁷ Ω cm, more preferably at least approximately 10⁻⁶ Ω cm and even more preferably at least approximately 10⁻⁵ 106 cm.

### DEPOSITION PARAMETERS FOR EXAMPLE 1

Xenon (Xe) is used as the sputter gas, with 1500 kV energy of the Xenon ion beam and a current of 200 mA. The bottom tantalum layer with a thickness of 50 nm was doped with nitrogen in the presence of a nitrogen flow of 30 sccm. On top of the tantalum layer a 20 nm thick TaON layer was deposited. This layer was doped with nitrogen using a nitrogen flow of 30 sccm and with oxygen using an oxygen flow of 15 sccm.

### MEASUREMENT RESULTS OF EXAMPLE 1

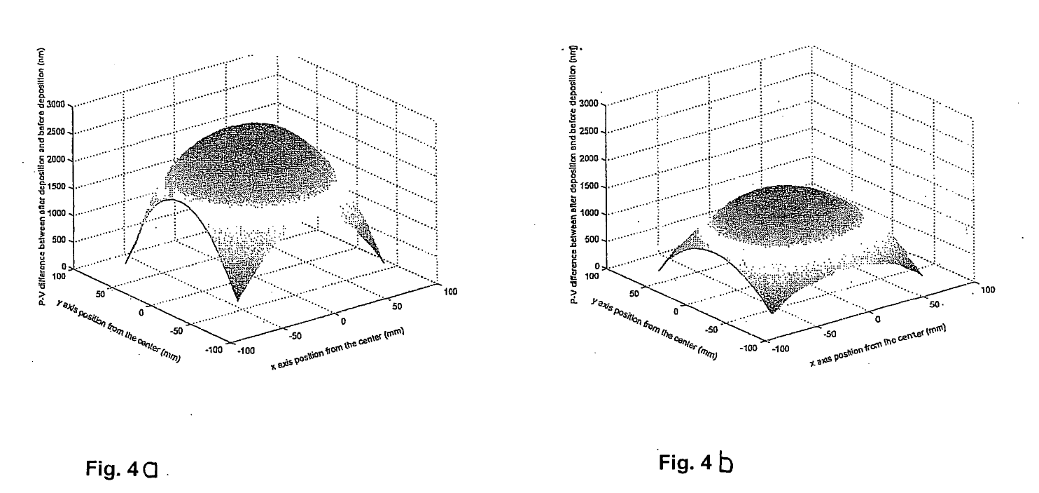

FIG. 4b shows a three-dimensional plot of stress induced in a tantalum nitride (TaN) film according to example 1, as measured by a peak-to-valley bending of said substrate after depositing said film, for ion beam sputtering (IBS) using Xenon (Xe) ions. The peak-to-valley bending is approx. 1.56 micron for a 6×6 Inch square photo mask blank. As is know to a person skilled in the art the value for the bending of the photo mask blank can be converted into stress values in units of MPa.

The tantalum nitride absorber layer showed a high etch selectivity with an etch bias of almost 0 with 100% over etch. Features smaller than 100 nm could be achieved, the CD uniformity was less than 10 nm.

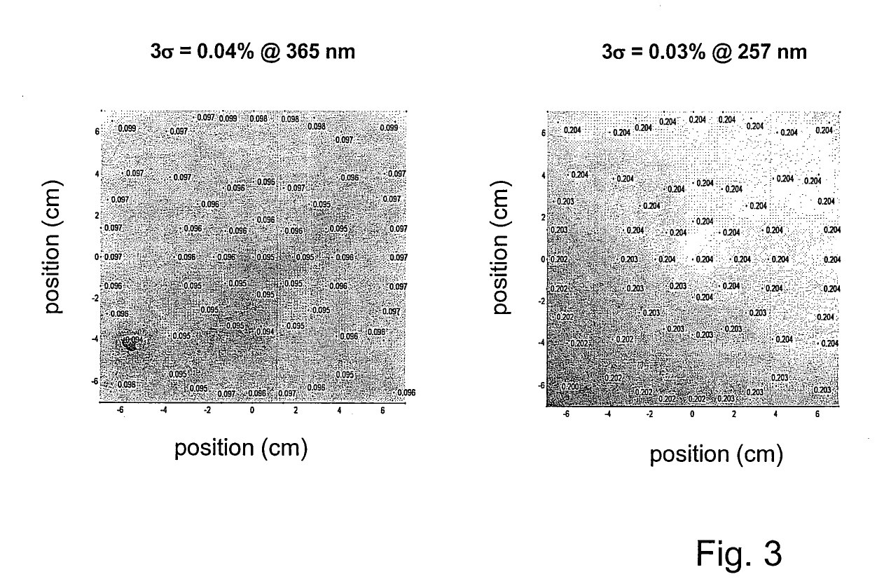

FIG. 3 shows results of reflection measurements at two different optical inspection wavelengths in the near ultraviolet spectral range in a two-dimensional plot of the photo mask blank according to example 1. At an optical inspection wavelength of 365 nm the variation of reflectivity of the TaON anti-reflection coating is smaller than 0.04% (3σ), at an optical inspection wavelength of 257 nm the variation of reflectivity of the TaON anti-reflection coating is smaller than 0.03% (3σ).

At an optical inspection wavelength of 365 nm a reflectivity of 5.4% was measured with an optical density (OD) of the TaON anti-reflection coating of 1.71. At an optical inspection wavelength of 257 nm a reflectivity of 19.7% was measured with an optical density (OD) of the TaON anti-reflection coating of 2.32. At an optical inspection wavelength of 193 nm a reflectivity of 26.1% was measured with an optical density (OD) of the TaON anti-reflection coating of 3.46.

The thickness uniformity is very high for this layer. A decrease in reflectivity for UV wavelengths can be determined by lowering the nitrogen flow in the vacuum chamber.

The EUV reflectivity, at a wavelength of 13.5 nm, of the high-reflective multi-layer stack shown in FIG. 1 with a patterned TaN absorber layer with a thickness of 55 nm deposited thereon is 99.4%.

The EUV reflectivity of the TaN absorber layer is approx. 0.6% at a wavelength of 13.2 nm and increases continuously to 0.11% at a wavelength of 14 nm.

Three out of thirty-six samples (8.3%) were free of any defects above 0.5 micron. Six out of thirty-six samples (16.6%) were free of any defects above 0.8 micron. On a 6×6 square Inch photo mask blank only seven defects occurred of a size larger than 0.2 micron PSL (polystyrene latex spheres), corresponding to a mean defect level or density of 0.035 defects per square centimeter. As is well known to a person skilled in the art polystyrene latex spheres are deposited on top of any blank or substrate for calibrating the detection of front side particles. Accordingly, PSL equivalent size corresponds to such detection calibration means.

### REFERENCE EXAMPLE 2

In a reference example, Argon (Ar) is used as the sputter gas, with 1500 kV energy of the first ion beam and a current of 200 mA. The bottom tantalum layer with a thickness of 50 nm was doped with nitrogen in the presence of a nitrogen flow of 30 sccm. On top of the tantalum layer a 20 nm thick TaON layer was deposited. This layer was doped with nitrogen using a nitrogen flow of 30 sccm and with oxygen using an oxygen flow of 15 sccm. Hence, besides using Ar ions instead of Xe ions, identical parameters were used for ion beam sputtering the TaN and TaON layers.

### MEASUREMENT RESULTS OF EXAMPLE 2

FIG. 4a shows a three-dimensional plot of stress induced in a tantalum nitride (TaN) film according to example 2, as measured by a peak-to-valley bending of said substrate after depositing said film, for ion beam sputtering (IBS) using Argon (Ar) ions. The peak-to-valley bending is approx. 2.62 micron for a 6×6 Inch square photo mask blank. Hence, for similar process parameters the stress induced in the tantalum nitride absorber layer is substantially higher when Argon ions are used as sputter gas for ion beam sputtering.

Further aspects according to the present invention concerning the conductive coating provided on the back surface of the substrate are disclosed in the applicant's co-pending U.S. patent application Ser. No. 10/825,618 filed on Apr. 16, 2004 ‘Mask blank for use in EUV lithography and method for its production’ and in the applicant's German patent application no. 103 17 792.2-51 filed on Apr. 16, 2003, the whole contents of which are hereby explicitly incorporated by reference for the purpose of disclosing the present invention.

As will become apparent to a person skilled in the art studying the above specification, many modifications and variations will become possible in light of the above disclosure. Therefore, it is intended that the appended claims shall be interpreted in the broadest possible manner and that any such modifications and variations claimed shall be covered by the scope of the appended claims as long as such modifications and variations are covered by the appended claims and the technical teaching disclosed herein.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

### REFERENCE NUMERALS

10 mask blank
11 substrate
12 high reflective multi-layer stack
13 capping layer
14 buffer layer
15 absorber layer
15a TaN absorber layer
15b TaON anti-reflection coating
16 electrically conductive coating on back surface of substrate

What we claim is:

1. A method for manufacturing of a mask blank for EUV photolithography, comprising the steps of:
providing a substrate having a front surface and a back surface;
depositing a film comprising tantalum nitride (TaN) on said front surface of said substrate for absorbing EUV light used during a photolithographic process; and
depositing a conductive coating on said back surface of said substrate.

2. The method of claim 1, wherein said step of depositing said film comprising tantalum nitride (TaN) on said front surface of said substrate comprises depositing said film by ion beam sputtering, said step of ion beam sputtering comprising directing a particle beam of ions onto a target within a vacuum chamber, said target consisting at least of tantalum.

3. The method of claim 2, wherein said step of directing a particle beam of ions onto said target comprises directing a particle beam of Xenon (Xe) ions onto said target.

4. The method of claim 3, wherein said step of ion beam sputtering is performed in the presence of a nitrogen gas within said vacuum chamber while directing said particle beam of Xenon (Xe) ions onto said target.

5. The method of claim 2, wherein said conductive coating on said back surface of said substrate is deposited using ion beam sputtering a conductive metal.

6. The method of claim 2, wherein said step of ion beam sputtering is performed such that a stress induced in said film, as measured by a peak-to-valley bending of said substrate after depositing said film, is better than 2.6 micron for a 6×6 Inch square substrate.

7. The method of claim 4, wherein said step of ion beam sputtering is performed such that a stress induced in said film, as measured by a peak-to-valley bending of said substrate after depositing said film, is better than 1.56 micron for a 6×6 Inch square substrate.

8. The method of claim 3, wherein said step of ion beam sputtering is performed such that a defect level of defects within said film of a size larger than 0.2 micron PSL is smaller than 0.035 defects per square centimeter at a limit below 200 nm, more preferably 0.001 defects per square centimeter at a limit below 150 nm and most preferably 0.001 defects per square centimeter at a limit below 50 nm.

9. The method of claim 3, wherein said step of ion beam sputtering is performed such that an absorption of said film at an extreme ultraviolet wavelength, preferably at a wavelength of 13.5 nm, is better than 97%, preferably better than 99% and most preferably better than 99.5%.

10. The method of claim 3, further comprising depositing an anti-reflection coating on said film being anti-reflective at an optical inspection wavelength in the range between 150 nm and 400 nm.

11. The method of claim 10, wherein said anti-reflection coating is TaON.

12. The method of claim 10, wherein said step of depositing said anti-reflection coating on said film is performed in the presence of an oxygen gas within said vacuum chamber while directing said particle beam of ions onto said target.

13. The method of claim 11, wherein a ratio of a thickness of said anti-reflection layer to a thickness of said film is within the range between 0.4 and 0.12.

14. The method of claim 11, wherein said step of depositing said anti-reflection coating on said film is conducted such that a variation of reflectivity at an optical inspection wavelength of 365 nm is smaller than 0.06% (3σ), preferably smaller than 0.05% (3σ) and most preferably smaller than 0.04% (3σ).

15. A mask blank for use in EUV photolithography, comprising:
a substrate having a front surface and a back surface; and
a reflective multilayer system on said front surface for reflecting light used for EUV photolithography; said mask blank further comprising:
at least one film comprising tantalum nitride (TaN) deposited on said front surface for at least attenuating light used for EUV photolithography; and
a conductive coating deposited on said back surface of said substrate.

16. The mask blank of claim 16, wherein said film comprising tantalum nitride (TaN) is deposited by ion beam sputtering comprising directing a particle beam of ions onto a target within a vacuum chamber, said target consisting at least of tantalum (Ta).

17. The mask blank of claim 17, wherein said film comprising tantalum nitride (TaN) is deposited by directing a particle beam of Xenon (Xe) ions onto said target.

18. The mask blank of claim 18, wherein said step of ion beam sputtering is performed in the presence of a nitrogen gas within said vacuum chamber while directing said particle beam of Xenon (Xe) ions onto said target.

19. The mask blank of claim 17, wherein a stress induced in said film, as measured by a peak-to-valley bending of said substrate after depositing said film, is better than 2.6 micron for a 6×6 Inch square substrate.

20. The mask blank of claim 18, wherein a stress induced in said film, as measured by a peak-to-valley bending of said substrate after depositing said film, is better than 1.56 micron for a 6×6 Inch square substrate.

21. The mask blank of claim 18, wherein a defect level of defects within said film of a size larger than 0.2 micron PSL is smaller than 0.035 defects per square centimeter at a limit below 200 nm, more preferably 0.001 defects per square centimeter at a limit below 150 nm and most preferably 0.001 defects per square centimeter at a limit below 50 nm.

22. The mask blank of claim 18, wherein an absorption of said film at an extreme ultraviolet wavelength, preferably at a wavelength of 13.5 nm, is better than 97%, preferably better than 99% and most preferably better than 99.5%.

23. The mask blank of claim 18, wherein an anti-reflection coating is provided on said film comprising tantalum nitride (TaN), said anti-reflection coating being anti-reflective at an optical inspection wavelength in the range between 150 nm and 400 nm.

24. The mask blank of claim 24, wherein said anti-reflection coating is TaON.

25. The mask blank of claim 25, wherein said anti-reflection coating on said film is deposited in the presence of an oxygen gas within said vacuum chamber while directing said particle beam of ions onto said target.

26. The mask blank of claim 25, wherein a ratio of a thickness of said anti-reflection layer to a thickness of said film is within the range between 0.4 and 0.12.

27. The mask blank of claim 25, wherein a variation of reflectivity at an optical inspection wavelength of 365 nm of said anti-reflection coating is smaller than 0.06% (3σ), preferably smaller than 0.05% (3σ) and most preferably smaller than 0.04% (3σ).
